(19) United States
(12) Patent Application Publication
(10) Pub. No.: US 2006/0013414 A1
(43) Pub. Date: Jan. 19, 2006

(54) METHODS AND RELATED CIRCUIT FOR AUTOMATIC AUDIO VOLUME LEVEL CONTROL

(76) Inventor: Hsuan-Huei SHIH, Taipei City (TW)

Correspondence Address: NORTH AMERICA INTELLECTUAL PROPERTY CORPORATION, P.O. BOX 506, MERRIFIELD, VA, 22116, US

(21) Appl. No.: 10/904,706

(22) Filed: Nov. 24, 2004

(30) Foreign Application Priority Data
Jul. 15, 2004 (TW) 093121163

(51) Int. Cl. H03G 3/00

(52) U.S. Cl. 381/107; 381/109

(57) ABSTRACT

Methods and related circuit for automatic volume-tracking and controlling of an audio signal. The audio signal has a plurality of sampled audio data, and the method includes: for each of the audio data, calculating a mean-volume data according to neighboring audio data; if the mean-volume data is larger than a recorded max-mean data, then updating the max-mean data, otherwise keeping the max-mean data not updated; and recording whether the max-mean data is updated. After performing aforementioned steps for a predetermined number of audio data, if the max-mean data is still not updated, then updating the max-mean data according to current mean-volume data. Thus the max-mean data can reflects local maximum volume of the audio signal, and the invention can control the volume of the audio signal accordingly.

### BACKGROUND OF INVENTION

1. Field of the Invention

The present invention provides methods and a related circuit for automatic audio volume level control, and more particularly, for tracking the local maximum of the volume of an audio signal, so as to control volume automatically.

2. Description of the Prior Art

Video programs from mass media provide news, knowledge, and entertainment for audiences, and people can choose what they want from the available programs. However, for commercial purposes, these programs are often alternated with advertisements. Moreover, in order to enhance commercial effect, some advertising spots are played at a higher volume. The higher the volume of the commercial spots during programs, the more uncomfortable these commercials are for the audiences. In this situation, audiences can only decrease the volume during commercial spots, and increase the volume again after commercial spots. Such repeated tuning down and up causes the audience inconvenience.

It is therefore a primary objective of the claimed invention to provide methods and a related circuit for automatic audio volume level control.

The claimed invention discloses a method for controlling volume automatically. The method comprises: receiving an audio signal comprising a plurality of audio data, the audio signal being capable of providing each audio data according to a default order; recording a max-mean data; applying a volume-tracking process to each audio data of the audio signal; and performing a volume adjustment process after applying the volume-tracking process to an audio data for setting the volume of the audio data according to the value of the max-mean data. The volume-tracking process comprising: when applying the volume-tracking process to the audio data, performing a volume detection step for selecting a plurality of audio data according to an order of the audio data in the audio signal, and calculating a corresponding mean-volume data according to the selected audio data; comparing the mean-volume data with the value of the max-mean data; if the mean-volume data is larger than the max-mean data, then performing an update step for updating the max-mean data according to the mean-volume data; recording whether the max-mean data is updated; and when applying the volume-tracking process to an audio data, if the max-mean data has not been updated after applying the volume-tracking process to a predetermined number of audio data prior to the audio data, then updating the value of the max-mean data according to the mean-volume data corresponding to the audio data.

The claimed invention further discloses a control circuit for controlling volume automatically. The control circuit comprises: a reception circuit for receiving an audio signal, the audio signal comprising a plurality of audio data, the audio signal capable of providing each audio data according to a default order; a data register module for recording a max-mean data; a volume-tracking module; and a volume adjustment module which is capable of adjusting the volume of the audio data according to the value of the max-mean data after the volume-tracking module processes an audio data. The volume-tracking module comprises: a volume detection module for selecting a plurality of audio data according to an order of each audio data in the audio signal, and calculating a corresponding mean-volume data according to the selected audio data; a comparison module for receiving the mean-volume data, and comparing the mean-volume data with the value of the max-mean data; an update module which is capable of updating the max-mean data according to the mean-volume data when the comparison module determines that the mean-volume data is larger than the max-mean data; a continuation-status register module for recording whether the max-mean data has been updated according to the status of whether the update module has updated the max-mean data; and a decision module which updates the value of the max-mean data according to the mean-volume data corresponding to the audio data when the volume detection module processes an audio data, if the continuation-status register module indicates that the max-mean data is not yet updated after applying the volume-tracking process to a predetermined number of audio data prior to the audio data.

The claimed invention further discloses a method for tracking dynamic volume. The method comprises: receiving an audio signal comprising a plurality of audio data, the audio signal capable of providing each audio data according to a default order; recording a max-mean data; and applying a volume-tracking process to each audio data of the audio signal. The volume-tracking process comprises: when taking the volume-tracking process to an audio data, performing a volume detection step for selecting a plurality of audio data according to an order of the audio data in the audio signal, and calculating a corresponding mean-volume data according to the selected audio data; comparing the mean-volume data with the value of the max-mean data; if the mean-volume data is larger than the max-mean data, then performing an update step for updating an original value of the max-mean data according to the mean-volume data; recording whether the max-mean data is updated or not; and when taking the volume-tracking process to an audio data, if the max-mean data is not yet updated after taking the volume-tracking process to a predetermined number of audio data prior to the audio data, then updating the value of the max-mean data according to the mean-volume data corresponding to the audio data.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 illustrates a block diagram of a control circuit in accordance with the present invention.

FIG. 2 shows a flowchart of the control circuit in FIG. 1 while performing a volume tracking/controlling process.

FIG. 3 and FIG. 4 illustrate schematic diagrams of related signals and data of the control circuit in FIG. 1.

FIG. 5 shows a flowchart of an embodiment of the present invention.

FIG. 6 illustrates a schematic diagram of related signals and data of the method in FIG. 5.

### DETAILED DESCRIPTION

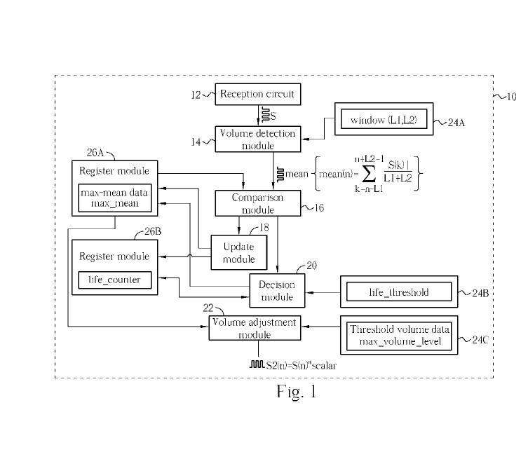

Please refer to FIG. 1, which illustrates a block diagram of a control circuit 10 in accordance with the present invention. The control circuit 10 can be used in any kind of audio-visual device, such as DVD, CD players, radios, TVs, screens with speakers, Hi-Fi equipment, or multimedia computers, to track and control volume automatically while playing audio signals. The control circuit 10 includes a reception circuit 12, a volume detection module 14, a comparison module 16, an update module 18, a decision module 20, a volume adjustment module 22 and register modules 24A, 24C, 26A, and 26B. The volume detection module 14, the comparison module 16, the update module 18, and the decision module 20 form a volume-tracking module. The register module 26A is a max-mean data register module for recording a max-mean data max_mean. The register module 26B is a continuation-status register module for recording a data life_counter. The reception circuit 12 receives an audio signal S, and gets audio data corresponding to each sampled point in the audio signal, where the audio data corresponding to the n'th sampled point is referred to as S(n). For example, if the control circuit 10 is in a CD player, the CD player can read and decode audio signal data from a CD with a reading system, and the reception circuit 12 can read the electronic audio signal from the reading system as an audio signal S.

An overview of the operation of the control circuit 10 is as follows. First, the volume detection module 14 of the control circuit 10 calculates a mean-volume data mean in response to each audio data sample S(n), representing the mean volume around the audio data S(n). Then, the control circuit 10 compares the mean-volume data mean with the max-mean data max_mean. If the mean-volume data mean is larger than the max-mean data max_mean, the control circuit 10 updates the max-mean data max_mean according to the mean-volume data mean, so as to make the max-mean data max_mean track the maximum volume of the audio signal S. Alternatively, if the mean-volume data mean is not larger than the max-mean data max_mean, the control circuit 10 does not update the max-mean data max_mean, and continues to accumulate the data life_counter, which represents the number of times of the max-mean data max_mean was not updated. After the control circuit 10 handles the audio data S(n), S(n+1), and S(n+2), if the data life_counter indicates that the number of times that the max-mean data max_mean has not been updated is greater than a default, the control circuit 10 updates the max-mean data max_mean to ensure that the max-mean data max_mean reflects the local maximum of the volume of the audio signal S. As a result, according to the max-mean data max_mean, the control circuit 10 can determine spots of high volume in the audio signal S properly, and therefore control the volume automatically, so as to decrease volume during the high-volume periods.

The operation of the control circuit 10 can be described in detail as follows. First, the volume detection module 14 calculates a mean-volume data mean corresponding to each of the audio data samples S(n). In a preferred embodiment of the present invention, the volume detection module 14 determines the mean-volume data mean corresponding to the audio data samples neighboring the audio data sample S(n). For example, as shown in FIG. 1, the mean-volume data mean corresponding to the audio data S(n) is a mean of the absolute values of the audio data samples in the range S(n−L1), S(n−L1+1), S(n−L1+2), . . . S(n+L1−2), S(n+L1−1), where L1 and L2 are two constants recorded in the register module 24A. In other words, the volume detection module 14 can calculate moving averages for each sampled point in the audio signal S, and ranges (or windows) of the moving averages are recorded in the register module 24A. According to the window ranges in the register module 24A, the volume detection module 14 can calculate the mean-volume data mean corresponding to each of the audio data samples S(n).

After the volume detection module 14 calculates the mean-volume data mean corresponding to each of the audio data samples S(n), the comparison module 16 compares the mean-volume data mean with the max-mean data max_mean in the register module 26A. If the mean-volume data mean is larger than the max-mean data max_mean, the update module 18 updates the max-mean data max_mean in the register module 26A. In the preferred embodiment of the present invention, the update module 18 can take the mean of the max-mean data max_mean and the mean-volume data mean before updating (that is, (max_mean+mean)/2) as an updated max-mean data max_mean. Meanwhile, the update module 18 resets the data life_counter in the register module 26B after updating the max-mean data max_mean, indicating that the max-mean data max_mean has been updated.

On the other hand, if the result of the comparison module 16 is that the mean-volume data mean is not larger than the max-mean data max_mean, the decision module 20 compares the data life_counter with a constant data life_threshold in the register module 24B. If the data life_counter is greater than the data life_threshold, meaning that the number of times that the max-mean data max_mean has not been updated is greater than a default, the decision module 16 updates the max-mean data max_mean. In this situation, the decision module 16 uses the mean of the max-mean data max_mean and the mean-volume data mean before updating as an updated max-mean data max_mean. Alternatively, if the data life_counter is not larger than the data life_threshold, the current max-mean data max_mean is not updated, but the decision module 20 updates the data life_counter in the register module 26B to continue to accumulate the data life_counter, indicating that the number of times the max-mean data max_mean has not been updated increased again.

During operation of the update module 18 and the decision module 20, the max-mean data max_mean reflects the local maximum volume of the audio signal S, and the volume adjustment module 22 of the control circuit 10 adjusts volume accordingly when playing the audio signal S. In the preferred embodiment of the present invention, the volume adjustment module 22 compares the max-mean data max_mean with the constant data max_volume_level in the register module 24C. The constant data max_volume_level is a threshold volume data. When the volume adjustment module 22 determines that the max-mean data max_mean is greater than the threshold volume data max_volume_level, the volume adjustment module 22 calculates a volume adjustment scalar (such as a value of max_volume_level/max_mean) which is smaller than 1, to create an adjusted audio data S2(n) by multiplying the original audio data S(n) by the scalar. Otherwise, if the max-mean data max_mean is not greater than the threshold volume data max_volume_level, the volume adjustment module 22 sets the scalar to 1. After adjusting the volume based on the scalar, the audio data S2(n) is output by the control circuit 10. By playing the audio data S2(n), the control circuit 10 can compensate for the high volume sequences in the audio signal S.

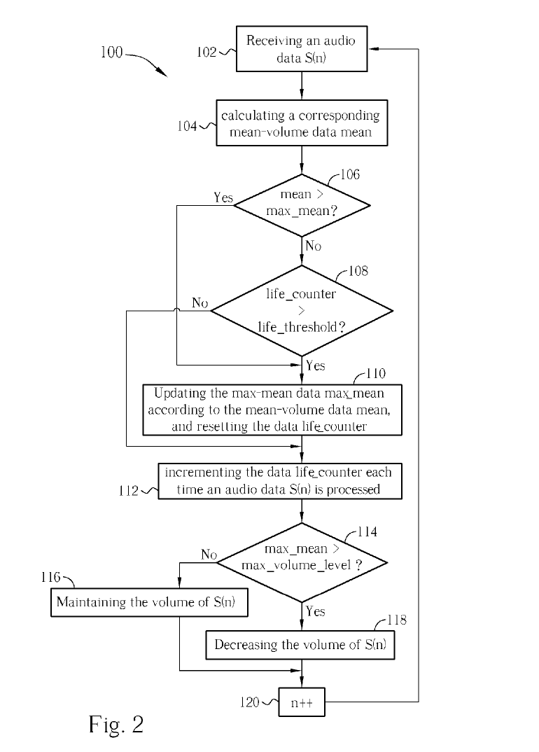

The above-mentioned operations of the control circuit 10 can be further described with an algorithm process as shown in FIG. 2. The process 100 handles each sampled audio signal S(n) in the audio signal S sequentially by the following steps:

Step 102: receiving an audio data S(n) from the audio signal S.

Step 104: calculating a corresponding mean-volume data mean according to the audio data neighboring the audio data S(n). This step can be performed by the volume detection module 14 in FIG. 1, so as to calculate a mean of a plurality of absolute values of audio data neighboring the audio data S(n) as the mean-volume data mean.

Step 106: determining whether the mean-volume data mean is larger than the max-mean data max_mean. If true, proceed to step 110 to update the max-mean data max_mean, else proceed to step 108.

Step 108: checking if the data life_counter is larger than the constant data life_threshold. If true, proceed to step 110, else proceed to step 112.

Step 110: Updating the max-mean data max_mean according to the mean-volume data mean, and resetting the data life_counter. As mentioned above, in the preferred embodiment of the present invention, a mean of the previous max-mean data max_mean and the current mean-volume data mean is taken as the updated max-mean data max_mean. Also, the data life_counter is set to 0.

Step 112: incrementing the data life_counter each time an audio data S(n) is processed. The data life_counter is incremented by 1.

Step 114: checking if the max-mean data max_mean is larger than the threshold volume data max_volume_level. If true, proceed to step 118, else proceed to step 116.

Step 116: set the volume adjustment scalar to 1, so as to maintain the volume of the audio data S(n).

Step 118: calculating a volume adjustment scalar (such as max_volume_level/max-mean) which is in the range 0 to 1, including 0 but not including 1, and multiplying the audio data S(n) by the scalar, so as to decrease the volume of the audio data S(n).

Step 120: incrementing n, so as to perform the process 100 for the next audio data in the audio signal S.

In the process 100, step 102 to 112 can be seen as a volume-tracking process, while step 114 to 118 can be seen as a volume adjustment process. After applying the volume-tracking process of process 100 to each of the audio data in the audio signal S, if the max-mean data max_mean is not updated, the data life_counter will not be reset in step 110, but be incremented in step 112. With progressive incrementing of the data life_counter, the data life_counter will become larger than the data life_threshold, and from step 114 to step 118, the data life_counter will be zeroed and the max-mean data max_mean will be updated. Alternately, in the present invention, the data life_counter could be implemented by decrementing until it reaches zero. That is, when resetting the data life_counter in step 110, the data life_counter is set to equal the data life_threshold; in step 112, the data life_counter is decremented by 1; in step 108, the decision is made according to whether the data life_counter is decreased to a value smaller than 0. No matter which method is chosen, the data life_counter and the constant data life_threshold are designed to limit the number of times that the max-mean data max_mean is not updated.

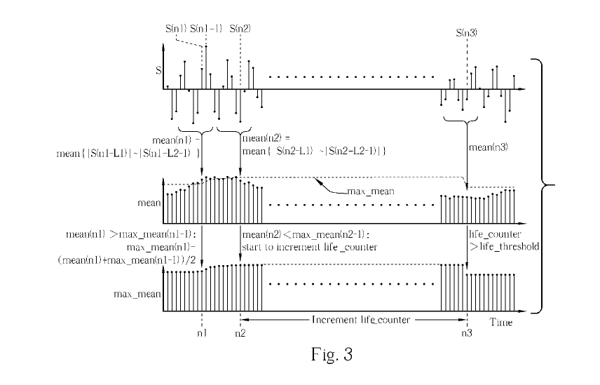

In order to further describe how to track volume with the max-mean data max_mean in FIG. 1 and FIG. 2, please refer to FIG. 3 (also FIG. 1 and FIG. 2), which illustrates a schematic diagram of related signals (the audio signal S, the mean-volume data mean and the max-mean data max_mean) of the present invention control circuit 10 in FIG. 1. In FIG. 3, the x-axis is time domain, while the y-axes are signal or data amplitudes. The audio signal S can provide audio data of a plurality of sampled points, such as audio data S(n1), S(n1+1) to S(n2), S(n3), etc, to represent volume corresponding to time domain. Because each of the audio signals includes a phase data of sound, the audio data can be positive or negative. Therefore, when performing the process 100 (as shown in FIG. 2) on the audio data S(n1), a mean of absolute values of the audio data S(n1−L1) to S(n1+L2−1) neighboring the audio data S(n1) is calculated for determining a mean of corresponding volumes. In FIG. 3, a notation “mean(n1)” represents a mean of volumes corresponding to the audio data S(n1). The process 100 compares the mean-volume data mean(n1) with the max-mean data max_mean stored in the register module 26A (please refer to FIG. 1). What should be noticed is, the max-mean data max_mean is set when the process 100 handles the prior audio data S(n−1), so the max-mean data max_mean is marked as “max_mean(n1−1)” in FIG. 3.

In the example of FIG. 3, because the audio data S(n1) is in a period of increasing volume, the audio data S(n1) is larger than the max-mean data max_mean(n1−1), and so the max-mean data max_mean should be updated according to the process 100 in FIG. 2. As mentioned above, in the preferred embodiment of the present invention, the max-mean data is updated to max_mean(n1) with a mean of the mean-volume data mean(n1) and the max-mean data max_mean(n1−1), and meanwhile, the data life_counter is reset. In addition, the max-mean data max_mean(n1) is recorded in the register module 26A to overwrite the previously recorded max-mean data max_mean(n1−1).

After finishing the audio data S(n1), the process 100 proceeds to the next audio data S(n1+1) for setting the corresponding max-mean data max_mean(n1+1), and so on. In FIG. 3, when applying the process 100 to the audio data S(n2), because the volume of the audio signal S decreases progressively after the audio data S(n2), the mean-volume data mean(n2) corresponding to the audio data S(n2) is smaller than the former one max-mean data max_mean(n2−1), so that the max-mean data max_mean is not updated (that is, max_mean(n2) is the same as max_mean(n2−1)), and the data life_counter is incremented. In the example of FIG. 3, if all the mean-volume data corresponding to the audio data after the audio data S(n2) of the audio signal S are smaller than the max-mean data max_mean, the max-mean data max_mean will not be updated and will continue to equal max-mean data max_mean(n2−1) after the process 100 processes these audio data, and the data life_counter will not be increased. In FIG. 3, a dashed line overlapping the diagram of the mean-volume data mean indicates the variation of the max-mean data max_mean.

If the data life_counter increases to a value greater than the constant data life_threshold when dealing with the audio data S(n3), the process 100 proceeds to step 110 (in FIG. 2), so as to update the max-mean data max_mean. The original max-mean data max_mean(n3−1) still equals the max_mean(n2−1). However, because the mean-volume data mean(n3) corresponding to the audio data S(n3) is smaller, the max-mean data max_mean(n3) becomes smaller after the max-mean data is updated to the max_mean(n3) according to a mean of the max-mean data max_mean(n3−1) and the mean(n3). In addition, after updating the max-mean data, the data life_counter is reset.

In short, the max-mean data max_mean of the present invention increases as the mean-volume data mean increases. When the mean-volume data is descending, the max-mean data max_mean stays at its local peak level for a default duration. During the duration, if the mean-volume data mean is smaller than the max-mean data max_mean, the present invention forces an update of the max-mean data max_mean, so as to track the mean-volume data. Moreover, the default duration is determined by whether the data life_counter is larger than the data life_threshold. Basically, the max-mean data max_mean is to track the maximum volume of the audio signal S, but the local maximum is much better for representing volume changes of different parts of the audio signal S. Furthermore, the data life_counter is used to make the max-mean data max_mean more representative of the local maximum volume, instead of the global maximum volume. Take FIG. 3 for example, without the data life_counter, the process 100 could not force an update of the max-mean data max_mean when processing the audio data S(n3), and this would make the max-mean data max_mean a global maximum.

From FIG. 3, other distinguishing features of the present invention can be described as follows. First, when updating the max-mean data max_mean, the present invention calculates the updated max-mean data according to the mean of the max-mean data from the time of the previous sample and the current mean volume data. As a result, even if the mean-volume data mean changes drastically and suddenly, the max-mean data max_mean will not change as the mean-volume data mean changes. For example, in FIG. 3, the mean-volume data mean of the audio signal S changes drastically between the audio data S(n1) and S(n2), but the max-mean data max_mean changes gently.

In addition, the present invention can use causal or non-causal systems for calculating the mean-volume data mean. In a real-time and causal system, the audio signal S provides each audio data according to time sequence. In other words, when applying the process 100 to an audio signal S(n), the control circuit 10 receives audio signals only before the audio signal S(n), such as the audio data S(n−1), S(n−2), etc. In this situation, the present invention calculates the mean-volume data according to the audio data before the audio data S(n). For example, as long as L1 is a positive number and L2 equals 1, the mean-volume data mean(n) corresponding to the audio data S(n) is calculated with a mean of absolute values of the audio data S(n−L1), S(n−L1+1), S(n−L1+2), to S(n). Because these audio data are before the audio data S(n), the control circuit 10 should have received these audio data when calculating the mean-volume data mean(n).

Conversely, in a non-real-time and non-causal system, before playing an audio data, the audio signal S can provide audio data after the audio data. For example, in some specifications of media data compression (such as MPEG, motion picture experts group), the decompression process of the audio signal S is non-causal. That is, before playing an audio data S(n), later audio data, such as audio data S(n+1), S(n+2), etc. have to be decompressed. In this situation, the present invention can also use audio data after the audio data S(n) for calculating the corresponding mean-volume data mean(n). For instance, as long as L1 and L2 are positive (and L2 is larger than 1), the mean-volume data mean(n) corresponding to the audio data S(n) is calculated with a mean of absolute values of the audio data S(n−L1), S(n−L1+1), S(n−L1+2), to S(n), or even to S(n+1), S(n+2), to S(n+L2−1). Furthermore, the present invention can calculate the mean-volume data by means of a weighted averages method. That is, when calculating the mean-volume data corresponding to the audio data S(n), the absolute values of the audio data S(n−L1), S(n−L1+1), etc. are multiplied by different weighted values first, and a mean of the weighted absolute values is calculated for the corresponding mean-volume data mean(n).

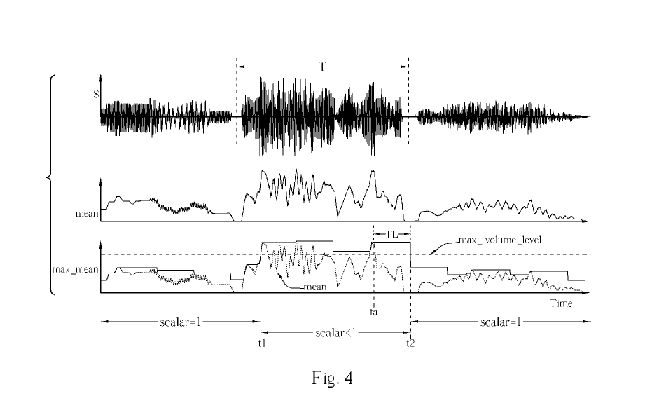

As to how the present invention automatically controls volume by using the max-mean data max_mean, please refer to FIG. 4 (also FIG. 1 and FIG. 2), which illustrates a waveform-to-time diagram of related signals and data of the present invention. The x-axis in FIG. 4 is time scale, and the y-axes are amplitudes of each signal and data. In FIG. 4, the audio signal S includes a sequence of high volume within a duration T, such as a commercial spot within a program. After time point t1, the max-mean data max_mean is larger than the threshold volume data max_volume_level as the volume of the audio signal S increases, so that the present invention starts to decrease the volume by using a smaller scalar (please refer to FIG. 1 and FIG. 2). Although the volume between time points t1 and t2 changes, the max-mean data max_mean stays within a range, and uses the data life_counter and life_threshold of the present invention to better reflect the sequence of high volume.

After the sequence of high volume finishes, the present invention forces an update of the max-mean data max_mean by testing the data life_counter against life_threshold, so as to track the local maximum after time point t2. As shown in FIG. 4, after the max-mean data max_mean reaches the local maximum at time point ta, the sequence of bursting volume is over. Therefore, the present invention starts to increment the data life_counter at time point ta. Through a duration TL and after time point t2, the present invention forces the max-mean data max_mean to discard the maximum volume of time point ta because the data life_counter becomes larger than the data life_threshold, and restarts tracking the local maximum after time point t2, which ensures that the max-mean data max_mean reflects the end of the high-volume sequence. Therefore, after time point t2, the present invention changes the scalar to 1 because the max-mean data max_mean is smaller than the threshold volume data max_volume_level.

There are three constant data for tracking/controlling volume: the data life_threshold, the threshold volume data max_volume_level, and the window range (or window, L1, and L2 shown in FIG. 1) for calculating the mean-volume data mean. When the present invention control circuit 10 is integrated into an audio-visual player, a user can set these constant data through an interface of the player, especially the threshold volume data, which controls the maximum volume when playing an audio signal. The player (or the control circuit 10 itself) should be capable of storing these constant data to use when performing the process 100. Of course, the player can establish common or preferred constant data as defaults initially. In addition, the player or the control circuit 10 can include transformation functions. For example, a user can set a duration (or the duration TL in FIG. 4) for the player or the control circuit 10 to force an update of the max-mean data with seconds or millisecond as units, so as to calculate the data life_threshold according to the sampling frequency of the audio signal (or, the duration TL divided by the sampling frequency).

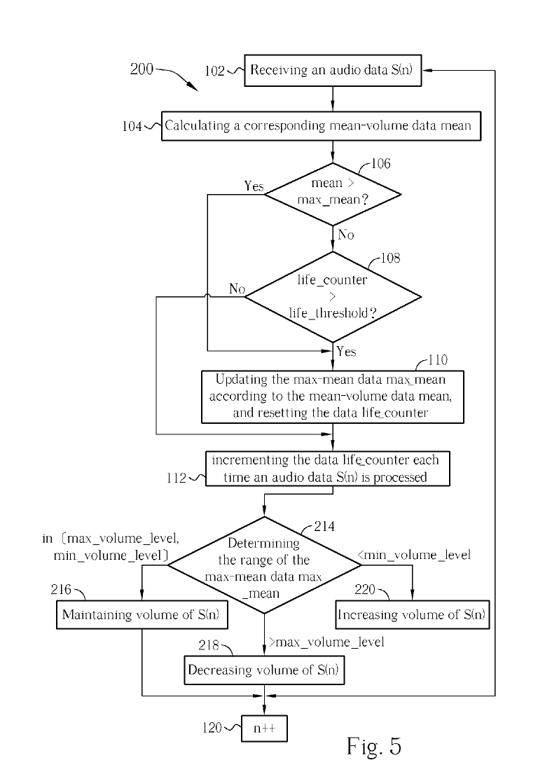

As mentioned above, in the process 100, step 114, 116, and 118 can be seen as a volume adjustment process. Excepting that the volume of the audio data S(n) is decreased when the max-mean data max_mean is larger than the threshold volume data max_volume_level, the present invention can adjust volume automatically by other methods, such as an automatic volume adjustment for very low volume. Please refer to FIG. 5, which illustrates a flowchart of another embodiment of a process 200 in accordance with the present invention. As in the process 100, steps 102 to 112 of the process 200 is the volume-tracking process, while the volume adjustment process of the process 200 for adjusting volume automatically according to the max-mean data max_mean is from step 214 to 220 (which can be implemented by the volume adjustment module 22 in FIG. 1). The volume-tracking process of the process 200 is the same as the volume-tracking process in FIG. 2, with the addition of the following steps:

Step 214: determining the range of the max-mean data max_mean. After steps 102 to 112, the process 200 has generated the max-mean data max_mean corresponding to the audio data S(n), so in this step, the range of the max-mean data max_mean can be determined. In addition, other than the maximum volume data max_volume_level, the process 200 can set another constant low threshold volume data min_volume_level, which is smaller than the threshold volume data max_volume_level, so the threshold volume data max_volume_level can be seen as a high threshold volume data. If the max-mean data max_mean is larger than the high threshold volume data max_volume_level, the process 200 proceeds to step 218. If the max-mean data max_mean is smaller than the low threshold volume data min_volume_level, the process 200 proceeds to step 220. If the max-mean data max_mean is between the high threshold volume data max_volume_level and the low threshold volume data min_volume_level, the process 200 proceeds to step 220.

Step 216: maintaining the volume of the audio data S(n).

Step 218: decreasing volume of the audio data S(n). As with step 118 of the process 100, in step 218, a volume adjustment scalar (such as max_volume_level/max-mean) smaller than 1 is calculated, and the audio data S(n) is multiplied by the scalar, so as to decrease the volume of the audio data S(n).

Step 220: increasing volume of the audio data S(n) if the max-mean data max_mean is smaller than the low threshold volume data min_volume_level. In step 220, a volume adjustment scalar (such as max_volume_level/max-mean) larger than 1 is calculated, and the audio data S(n) is multiplied by the scalar, so as to increase the volume of the audio data S(n).

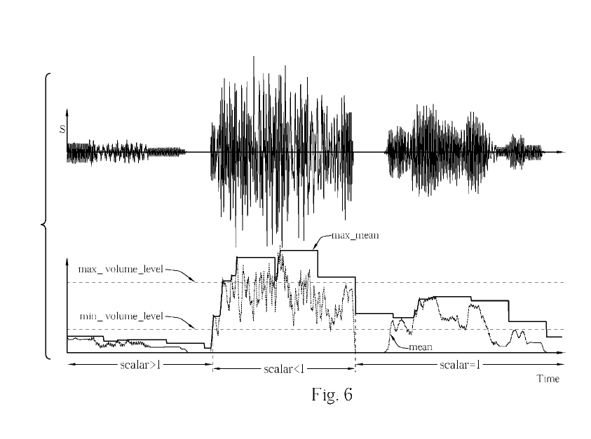

Please refer to FIG. 6 (also FIG. 5), which illustrates a schematic diagram of related signals when implementing the process 200. In FIG. 6, the x-axis is time domain, while the y-axes are signal or data amplitudes. In FIG. 6, the audio signal S includes three parts with different volume. The max-mean data max_mean of the present invention can track the local maximum of volume in an audio signal. If the max-mean data max_mean is smaller than the low threshold volume data min_volume_level, the present invention increases the volume of the audio signal with a scalar larger than 1. Conversely, if the max-mean data max_mean is larger than the high threshold volume data max_volume_level, the present invention decreases the volume of the audio signal with a scalar smaller than 1. However, if the max-mean data max_mean is between the high and the low threshold volume data, the present invention maintains the volume of the audio signal S.

In other words, because the max-mean data max_mean can track the local maximum of volume efficiently when performing the volume-tracking process, the present invention can not only increase volume when volume is low, but also decrease volume when volume is high as shown in the process 200. With the process 200, the control circuit 10 in FIG. 1 can include a register module for restoring the low threshold volume data min_volume_level, and a user can set the low threshold volume data min_volume_level through an interface. In addition, the volume adjustment module 22 of the control circuit 10 can be controlled through the interface for choosing a mode of the volume adjustment process. For example, the volume adjustment module 22 can decrease volume only when the volume is too high (that is, the process 100), or decrease/increase volume when the volume is too high/low (that is, the process 200). This process can also be used to increase volume only when the volume is too low, and follows from the above, as those skilled in the art will recognize; however, for the sake of brevity, discussion of this will be omitted.

In summary, in contrast to the prior art, the present invention can track the local maximum volume of the audio signal automatically, so as to control volume of the audio signal during playing, decreasing the discomfort of high-volume sequences. As mentioned above, in a TV program, commercial spots are often played with louder volume, so the present invention can also detect commercial spots through volume tracking. In the embodiment of FIG. 1, each module can be implemented with software, firmware, or hardware. For example, the volume detection module 14, the comparison module 16, the update module 18, the decision module 20, and the volume adjustment module 22 can be implemented on a single chip.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for controlling volume automatically, comprising:
receiving an audio signal comprising a plurality of audio data, the audio signal being capable of providing each audio data according to a default order;
recording a max-mean data;
applying a volume-tracking process to each audio data of the audio signal, the volume-tracking process comprising:
when applying the volume-tracking process to the audio data, performing a volume detection step for selecting a plurality of audio data according to an order of the audio data in the audio signal, and calculating a corresponding mean-volume data according to the selected audio data;
comparing the mean-volume data with the value of the max-mean data;
if the mean-volume data is larger than the max-mean data, then performing an update step for updating the max-mean data according to the mean-volume data;
recording whether the max-mean data is updated;
when applying the volume-tracking process to an audio data, if the max-mean data has not been updated after applying the volume-tracking process to a predetermined number of audio data prior to the audio data, then updating the value of the max-mean data according to the mean-volume data corresponding to the audio data; and
performing a volume adjustment process after applying the volume-tracking process to an audio data for setting the volume of the audio data according to the value of the max-mean data.

2. The method of claim 1, wherein when applying the volume detection step to a different audio data, a different plurality of audio data is selected in response to the different audio data for calculating each mean-volume data corresponding to each audio data.

3. The method of claim 1, wherein when performing the volume detection step, a mean is calculated according to absolute values of the selected audio signal for calculating the mean-volume data.

4. The method of claim 1, wherein after applying the volume-tracking process to an audio data and when performing the volume adjustment process, the volume adjustment process comprises:
comparing the max-mean data with a default threshold volume data; and
if the max-mean data is larger than the threshold volume data, then decreasing volume when playing the audio data.

5. The method of claim 4, further comprising: when the max-mean data is smaller than the threshold volume data, maintaining volume when playing the audio data.

6. The method of claim 1, wherein when applying the volume detection step to an audio data, a predetermined number of audio data prior to the audio data are selected for calculating the mean-volume data.

7. The method of claim 1, further comprising:
when applying the volume-tracking process to an audio data, if the max-mean data is not yet updated after applying the volume-tracking process to a predetermined number of audio data prior to the audio data, then updating the value of the max-mean data and recording that the max-mean data is updated.

8. A control circuit for controlling volume automatically, comprising:
a reception circuit for receiving an audio signal, the audio signal comprising a plurality of audio data, the audio signal capable of providing each audio data according to a default order;
a data register module for recording a max-mean data;
a volume-tracking module, comprising:
a volume detection module for selecting a plurality of audio data according to an order of each audio data in the audio signal, and calculating a corresponding mean-volume data according to the selected audio data;
a comparison module for receiving the mean-volume data, and comparing the mean-volume data with the value of the max-mean data;
an update module which is capable of updating the max-mean data according to the mean-volume data when the comparison module determines that the mean-volume data is larger than the max-mean data;
a continuation-status register module for recording whether the max-mean data has been updated according to the status of whether the update module has updated the max-mean data;
a decision module which updates the value of the max-mean data according to the mean-volume data corresponding to the audio data when the volume detection module processes an audio data, if the continuation-status register module indicates that the max-mean data is not yet updated after applying the volume-tracking process to a predetermined number of audio data prior to the audio data; and
a volume adjustment module which is capable of adjusting the volume of the audio data according to the value of the max-mean data after the volume-tracking module processes an audio data.

9. The control circuit of claim 8, wherein when processing a different audio data, the volume detection module selects a different plurality of audio data in response to the different audio data for calculating each mean-volume data corresponding to each audio data.

10. The control circuit of claim 8, wherein the volume detection module calculates a mean according to absolute values of the selected audio data for calculating the mean-volume data.

11. The control circuit of claim 8, wherein after the volume-tracking module processes an audio data and when the volume adjustment module adjusts the volume of the audio data, the volume adjustment module compares the max-mean data with a default threshold volume data, and if the max-mean data is larger than the threshold volume data, then the volume adjustment module decreases the volume of the audio data.

12. The control circuit of claim 11, wherein if the max-mean data is smaller than the threshold volume data, then the volume adjustment module does not change the volume of the audio data.

13. The control circuit of claim 8, wherein when dealing with an audio data, the volume detection module selects a predetermined number of audio data prior to the audio data for calculating the mean-volume data.

14. The control circuit of claim 8, wherein after the decision module updates the value of the max-mean data in the data register module, the continuation-status register module records that the max-mean data is updated.

15. A method for tracking dynamic volume, comprising:
receiving an audio signal comprising a plurality of audio data, the audio signal capable of providing each audio data according to a default order;
recording a max-mean data;
applying a volume-tracking process to each audio data of the audio signal, the volume-tracking process comprising:
when taking the volume-tracking process to an audio data, performing a volume detection step for selecting a plurality of audio data according to an order of the audio data in the audio signal, and calculating a corresponding mean-volume data according to the selected audio data;
comparing the mean-volume data with the value of the max-mean data;
if the mean-volume data is larger than the max-mean data, then performing an update step for updating an original value of the max-mean data according to the mean-volume data;
recording whether the max-mean data is updated or not; and
when taking the volume-tracking process to an audio data, if the max-mean data is not yet updated after taking the volume-tracking process to a predetermined number of audio data prior to the audio data, then updating the value of the max-mean data according to the mean-volume data corresponding to the audio data.

16. The method of claim 15, wherein when taking the volume detection step to different audio data, different plurality of audio data are selected in response to the different audio data for calculating each mean-volume data corresponding to each audio data.

17. The method of claim 15, wherein when performing the volume detection step, a mean is calculated according to absolute values of the selected audio signal for calculating the mean-volume data.

18. The method of claim 15, further comprising: if the max-mean data is smaller than the threshold volume data, then not changing the value of the max-mean data.

19. The method of claim 15, wherein when applying the volume detection step to an audio data, selecting a predetermined number of audio data prior to the audio data for calculating the mean-volume data.

20. The method of claim 15, further comprising:
when applying the volume-tracking process to an audio data, if the max-mean data is not yet updated after applying the volume-tracking process to a predetermined number of audio data prior to the audio data, then updating the value of the max-mean data and recording that the max-mean data is updated.
